(19) United States
(12) Patent Application Publication
(10) Pub. No.: US 2026/0320238 A1
(43) Pub. Date: Oct. 15, 2026

(54) ELECTRONIC DEVICE AND METHOD FOR GENERATING THREE-DIMENSIONAL SPATIAL DATA

(71) Applicant: MORAI INC., Seoul (KR)

(72) Inventors: Youhyeon BOO, Seoul (KR); Hyunjin PARK, Seoul (KR); Soojeong HAN, Seoul (KR)

(21) Appl. No.: 19/692,448

(22) Filed: May 29, 2026

Related U.S. Application Data
(63) Continuation of application No. PCT/KR2024/003453, filed on Mar. 19, 2024.

(30) Foreign Application Priority Data
Nov. 29, 2023 (KR) 10-2023-0169406

(51) Int. Cl. G06F 30/15; G06T 17/05; G06T 17/20

(52) U.S. Cl. CPC G06F 30/15; G06T 17/05; G06T 17/20

(57) ABSTRACT

An electronic device includes a communication circuit, a memory, and a processor operatively connected to the communication circuit and the memory. The processor is configured to receive a plurality of contents from at least one external electronic device connected through the communication circuit, generate a plurality of three-dimensional sub-data based on the received plurality of contents, and generate three-dimensional spatial data by merging the generated plurality of three-dimensional sub-data.

### CROSS-REFERENCE TO RELATED APPLICATIONS

This application is a continuation of International Application No. PCT/KR2024/003453, filed Mar. 19, 2024, which claims the benefit of priority under 35 U.S.C. § 119(a) to Korean Patent Application No. 10-2023-0169406, filed Nov. 29, 2023, in the Korean Intellectual Property Office, the entire disclosures of which are incorporated herein by reference.

### TECHNICAL FIELD

The present disclosure relates to an electronic device and method for generating three-dimensional spatial data.

### BACKGROUND

Due to the development of computing technology, spatial information technology that may accurately model a specific space or accurately represent three-dimensional spatial information is being developed. Such spatial information technology may provide three-dimensional spatial data so as to implement a three-dimensional space close to reality and may be used in industrial fields based on spatial information.

Meanwhile, due to the continuous increase of industrial fields based on spatial information, rapid and precise data construction and updating of spatial information is required. Accordingly, in generating three-dimensional spatial data, it is desirable to develop technology for utilizing various contents including spatial information.

### Technical Problem

The present disclosure provides an electronic device and method for generating three-dimensional spatial data to solve the problems described above.

### SUMMARY

The present disclosure may be implemented in various ways including a method, an apparatus (system), and/or a computer program stored in a computer-readable storage medium.

In some embodiments, an electronic device includes a communication circuit, a memory, and a processor operatively connected to the communication circuit and the memory. The processor is configured to receive a plurality of contents from at least one external electronic device connected through the communication circuit, generate a plurality of three-dimensional sub-data based on the received plurality of contents, and generate three-dimensional spatial data by merging the generated plurality of three-dimensional sub-data.

In some embodiments, the plurality of contents includes road map data. The processor is further configured to generate first three-dimensional sub-data associated with a road included in the three-dimensional spatial data, based on point cloud data included in the road map data.

In some embodiments, the plurality of contents includes digital topographic data. The processor is further configured to generate second three-dimensional sub-data associated with terrain included in the three-dimensional spatial data, based on contour line information included in the digital topographic data.

In some embodiments, the processor is further configured to generate digital elevation model (DEM) data based on the contour line information and generate the second three-dimensional sub-data associated with the terrain based on the digital elevation model data. The digital elevation model data is generated using an interpolation method. The second three-dimensional sub-data is generated using triangulation.

In some embodiments, the plurality of contents includes digital topographic data. The processor is further configured to generate third three-dimensional sub-data associated with buildings included in the three-dimensional spatial data, based on information related to the buildings included in the digital topographic data.

In some embodiments, the processor is further configured to generate three-dimensional mesh data related to a specific building based on outline coordinate information of the specific building and height information of the specific building among the information related to the buildings, obtain a texture image of the specific building based on usage information of the specific building among the information related to the buildings, apply the texture image of the specific building to the three-dimensional mesh data related to the specific building, and set an elevation value to the three-dimensional mesh data to which the texture image of the specific building is applied, based on an elevation value of the specific building among the information related to the buildings.

In some embodiments, the plurality of contents includes vegetation position information. The processor is further configured to generate fourth three-dimensional sub-data associated with vegetation included in the three-dimensional spatial data based on the vegetation position information. Generating the fourth three-dimensional sub-data associated with the vegetation may include adding an elevation value of a specific vegetation object to coordinate information of the specific vegetation object included in the vegetation position information and generate three-dimensional model data related to the specific vegetation object based on the coordinate information to which the elevation value is added.

In some embodiments, the processor is further configured to generate fifth three-dimensional sub-data associated with a static object included in the three-dimensional spatial data, based on a tagging table related to the static object including a road surface.

In some embodiments, the plurality of contents includes at least one of an orthophotograph or land cover data. The processor is further configured to generate sixth three-dimensional sub-data associated with terrain or a static object included in the three-dimensional spatial data based on the at least one of the orthophotograph or the land cover data. Generating sixth three-dimensional sub-data associated with the terrain may include generating a texture image of the terrain.

In some embodiments, a method of generating three-dimensional spatial data, performed by at least one processor is provided. The method includes receiving a plurality of contents from at least one external electronic device connected through a communication circuit, generating a plurality of three-dimensional sub-data based on the received plurality of contents, and generating the three-dimensional spatial data by merging the generated plurality of three-dimensional sub-data.

According to some embodiments of the present disclosure, by generating three-dimensional spatial data through merging of a plurality of three-dimensional sub-data generated based on a plurality of contents, rapid and precise data construction and updating for the three-dimensional spatial data may be supported.

The effects of the present disclosure are not limited to the effects mentioned above, and other effects not mentioned may be clearly understood by those of ordinary skill in the art to which the present disclosure pertains (referred to as “those skilled in the art”) from the description of the claims.

### BRIEF DESCRIPTION OF THE DRAWINGS

Embodiments of the present disclosure will be described with reference to the accompanying drawings described below, wherein like reference numerals indicate like elements, but are not limited thereto.

FIG. 1 illustrates a configuration of an electronic device for generating three-dimensional spatial data according to an embodiment of the present disclosure.

FIG. 2 is a schematic diagram illustrating a configuration in which an information processing system is communicatively connected to a plurality of user terminals, in relation to data processing according to an embodiment of the present disclosure.

FIG. 3 is a block diagram illustrating an internal configuration of a user terminal and an information processing system according to an embodiment of the present disclosure.

FIG. 4 illustrates a method of generating three-dimensional sub-data associated with a road according to an embodiment of the present disclosure.

FIG. 5 illustrates a method of generating three-dimensional sub-data associated with terrain according to an embodiment of the present disclosure.

FIG. 6 illustrates a method of generating three-dimensional sub-data associated with a building according to an embodiment of the present disclosure.

FIG. 7 illustrates a method of generating three-dimensional sub-data associated with vegetation according to an embodiment of the present disclosure.

FIG. 8 illustrates a method of generating three-dimensional sub-data associated with a static object according to an embodiment of the present disclosure.

FIG. 9 illustrates a method of generating three-dimensional sub-data associated with terrain or a static object according to an embodiment of the present disclosure.

FIG. 10 illustrates a method of generating three-dimensional spatial data according to an embodiment of the present disclosure.

### DETAILED DESCRIPTION

Hereinafter, specific details for carrying out the present disclosure will be described in detail with reference to the accompanying drawings. However, in the following description, if there is a concern that the gist of the present disclosure may be unnecessarily obscured, detailed descriptions of well-known functions or configurations will be omitted.

In the accompanying drawings, the same or corresponding components are given the same reference numerals. In addition, in the description of the following embodiments, repeated descriptions of the same or corresponding components may be omitted. However, even if descriptions of components are omitted, such components are not intended to be excluded from any embodiment.

Advantages and features of the disclosed embodiments, and methods of achieving them, will become clear with reference to the embodiments described below together with the accompanying drawings. However, the present disclosure is not limited to the embodiments disclosed below, but may be implemented in various different forms, and the present embodiments are merely provided to make the present disclosure complete and to fully inform those skilled in the art of the scope of the invention.

Terms used in the present specification will be briefly described, and the disclosed embodiments will be described in detail. The terms used in the present specification have been selected from general terms currently widely used as much as possible while considering functions in the present disclosure but may vary depending on the intentions of those skilled in the related field, precedents, or the emergence of new technologies. In addition, in specific cases, there are also terms arbitrarily selected by the applicant, and in such cases, the meaning will be described in detail in the corresponding description of the invention. Therefore, the terms used in the present disclosure should be defined based on the meaning of the terms and the overall content of the present disclosure, rather than simply the names of the terms.

In the present specification, singular expressions include plural expressions unless the context clearly specifies the singular. In addition, plural expressions include singular expressions unless the context clearly specifies the plural. Throughout the specification, when a part is said to include a certain component, this means that the part may further include other components rather than excluding other components, unless specifically stated to the contrary.

In addition, the terms “module” or “unit” used in the specification refer to software or hardware components, and the “module” or “unit” performs certain roles. However, the “module” or “unit” is not meant to be limited to software or hardware. The “module” or “unit” may be configured to reside in an addressable storage medium or may be configured to reproduce one or more processors. Therefore, as an example, the “module” or “unit” may include components such as software components, object-oriented software components, class components, and task components, processes, functions, attributes, procedures, subroutines, segments of program code, drivers, firmware, microcode, circuits, data, databases, data structures, tables, arrays, or variables. Components and the functionality provided in the “modules” or “units” may be combined into a smaller number of components and “modules” or “units” or further separated into additional components and “modules” or “units.”

According to an embodiment of the present disclosure, the “module” or “unit” may be implemented with a processor and a memory. The “processor” should be broadly interpreted to include a general-purpose processor, a central processing unit (CPU), a microprocessor, a digital signal processor (DSP), a controller, a microcontroller, a state machine, and the like. In some environments, the “processor” may also refer to an application specific integrated circuit (ASIC), a programmable logic device (PLD), a field programmable gate array (FPGA), and the like. The “processor” may also refer to a combination of processing devices such as, for example, a combination of a DSP and a microprocessor, a combination of a plurality of microprocessors, a combination of one or more microprocessors in conjunction with a DSP core, or a combination of any other such configurations. In addition, the “memory” should be broadly interpreted to include any electronic component capable of storing electronic information. The “memory” may also refer to various types of processor-readable media such as random access memory (RAM), read-only memory (ROM), non-volatile random access memory (NVRAM), programmable read-only memory (PROM), erasable-programmable read-only memory (EPROM), electrically erasable PROM (EEPROM), flash memory, magnetic or optical data storage devices, registers, and the like. A memory is said to be in electronic communication with a processor if the processor can read information from and/or write information to the memory. A memory integrated with a processor is in electronic communication with the processor.

In addition, terms such as first, second, A, B, (a), (b), and the like used in the following embodiments are only used to distinguish a certain component from another component, and the essence, order, or sequence of the corresponding component is not limited by the term.

In addition, in the following embodiments, when a component is described as being “connected,” “coupled,” or “linked” to another component, it should be understood that the component may be directly connected or linked to the other component, but another component may also be “connected,” “coupled,” or “linked” between each component.

In addition, “comprises” and/or “comprising” used in the following embodiments do not exclude the presence or addition of one or more other components, steps, operations, and/or elements that are referenced.

Hereinafter, various embodiments of the present disclosure will be described in detail with reference to the accompanying drawings.

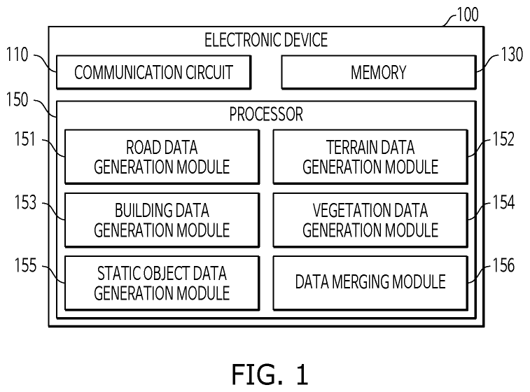

FIG. 1 illustrates a configuration of an electronic device 100 for generating three-dimensional spatial data according to an embodiment of the present disclosure. Referring to FIG. 1, the electronic device 100 for generating three-dimensional spatial data may include a communication circuit 110, a memory 130, and a processor 150. However, the configuration of the electronic device 100 is not limited thereto. According to various embodiments, the electronic device 100 may further include at least one other component in addition to the components described above. For example, the electronic device 100 may further include a display. In this case, the electronic device 100 may display, on the display, the contents received through the communication circuit 110 and/or contents generated by the processor.

Before describing the components of the electronic device 100 in further detail, conventional approaches for generating three-dimensional spatial data and their technical limitations are briefly described to provide context for the technical improvements offered by the electronic device 100. Conventional manual modeling approaches require human operators to construct each three-dimensional object individually, which consumes substantial time and computational resources and is therefore impractical for rapid updating of large-scale three-dimensional spatial data required by applications such as autonomous driving simulation and digital twin construction. Conventional automated approaches that rely on a single source of spatial information (for example, point cloud data alone, or satellite imagery alone) are limited in accuracy because no single data source captures all categories of objects (e.g., roads, terrain, buildings, vegetation, and static objects) with sufficient fidelity. For example, point cloud data alone may capture road geometry but lacks semantic information regarding building usage, while satellite imagery may capture surface textures but cannot resolve sub-canopy or vertical structure. Furthermore, conventional approaches that combine multiple data sources by independently processing each source and concatenating the results suffer from misalignment artifacts at object boundaries (e.g., buildings appearing to float above terrain, roads passing through hillsides, or vegetation embedded below ground level) because elevation values associated with different categories of objects are derived from different data sources and are not reconciled to a common geometric reference. The electronic device 100 according to embodiments of the present disclosure addresses these technical limitations through the architectural arrangements described in further detail below.

The communication circuit 110 may support establishment of a direct (e.g., wired) communication channel or a wireless communication channel between the electronic device 100 and an external electronic device, and may support performing communication through the established communication channel. According to an embodiment, the electronic device 100 may receive a plurality of contents from at least one external electronic device connected through the communication circuit 110. For example, the electronic device 100 may receive the plurality of contents from any one external electronic device through the communication circuit 110. As another example, the electronic device 100 may receive at least one different content from different external electronic devices through the communication circuit 110. Here, the contents include source information (or data) for generating three-dimensional spatial data and may be provided in various forms (or formats). For example, the contents may include at least one of road map data, digital topographic data, vegetation position information, a tagging table related to a static object comprising a road surface, an orthophotograph, or land cover data. However, the type of contents is not limited thereto, and may include documents, datasheets, files, and the like, comprising text, symbols, images, videos, and the like. According to an embodiment, some of the contents described above may be obtained from a server operated by a national institution or a local government. For example, the road map data, the digital topographic data, and the like may be obtained from a server operated by the National Geographic Information Institute (NGII), and the vegetation position information and the like may be obtained from a server operated by the local government.

The memory 130 may store various data used by at least one component (e.g., the processor 150) of the electronic device 100. The data may include, for example, input data or output data for software (or programs) and instructions related thereto. The memory 130 may include a volatile memory or a non-volatile memory. According to an embodiment, the memory 130 may store the contents received through the communication circuit 110.

The processor 150 may execute software (or a program) to control at least one other component (e.g., a hardware or software component) of the electronic device 100 connected to the processor 150 and may perform various data processing or operations. According to an embodiment, as at least part of the data processing or operations, the processor 150 may load instructions or data received from another component (e.g., the communication circuit 110) into a volatile memory, process the instructions or data stored in the volatile memory, and store result data in a non-volatile memory.

According to an embodiment, the processor 150 may generate a plurality of three-dimensional sub-data based on a plurality of contents and generate three-dimensional spatial data by merging the generated plurality of three-dimensional sub-data. To this end, the processor 150 may include a road data generation module 151, a terrain data generation module 152, a building data generation module 153, a vegetation data generation module 154, a static object data generation module 155, and a data merging module 156. However, the types of modules included in the processor 150 are classified according to functions related to the generation of three-dimensional spatial data, and the types and number thereof are not limited thereto. In addition, at least one of the modules included in the processor 150 may be implemented in the form of instructions stored in the memory 130.

The road data generation module 151 may generate three-dimensional sub-data associated with a road. According to an embodiment, the road data generation module 151 may generate three-dimensional sub-data associated with the road included in the three-dimensional spatial data, based on point cloud data included in the road map data. The road data generation module 151 may generate three-dimensional mesh data for the road based on the point cloud data included in the road map data using Delaunay triangulation, etc. For example, the three-dimensional sub-data associated with the road may include the three-dimensional mesh data for the road. As such, the road data generation module 151 may convert the road map data into a data form (or format) that is easy to output for autonomous driving simulation or three-dimensional asset (3D asset). In this process, the road data generation module 151 may set an elevation value of the road to an elevation value read from digital elevation model data described later. For example, the road data generation module 151 may set the elevation value of the road in a process of generating the three-dimensional mesh data for the road using an elevation value included in the digital elevation model data generated in a process in which the terrain data generation module 152 generates three-dimensional sub-data associated with the terrain. Accordingly, the road data generation module 151 may position the road to fit the terrain. In addition, for point data such as signs or traffic lights included in the road map data, the road data generation module 151 may use 3D assets pre-stored in the memory 130 in relation to the corresponding position.

The terrain data generation module 152 may generate three-dimensional sub-data associated with the terrain. According to an embodiment, the terrain data generation module 152 may generate three-dimensional sub-data associated with the terrain included in the three-dimensional spatial data, based on contour line information included in the digital topographic data. The terrain data generation module 152 may generate digital elevation model (DEM) data based on the contour line information included in the digital topographic data and generate three-dimensional mesh data for the terrain based on the digital elevation model data. For example, the three-dimensional sub-data associated with the terrain may include the three-dimensional mesh data for the terrain. In addition, the digital elevation model data may be generated using interpolation, and the three-dimensional mesh data for the terrain may be generated using triangulation. To describe in more detail, the terrain data generation module 152 may extract the contour line information included in the digital topographic data. At this time, when the elevation value of the contour line includes characters, the terrain data generation module 152 may convert the elevation value into numbers. Then, the terrain data generation module 152 may generate the digital elevation model data using an interpolation method (e.g., a Triangulated Irregular Network (TIN) interpolation method or an Inverse Distance Weighted (IDW) interpolation method). At this time, the digital elevation model data may be generated in a raster format. Then, the terrain data generation module 152 may generate the three-dimensional mesh data for the terrain according to the elevation value included in the digital elevation model data using triangulation (e.g., Delaunay triangulation). For example, the terrain data generation module 152 may generate a TIN terrain model according to the DEM elevation height. In this process, the terrain data generation module 152 may perform functions such as data conversion, optimization, or extraction using GIS (Geographic Information System) software (e.g., Quantum GIS (QGIS)) or a python script.

The building data generation module 153 may generate three-dimensional sub-data associated with a building. According to an embodiment, the building data generation module 153 may generate three-dimensional sub-data associated with the building included in the three-dimensional spatial data, based on information related to the building included in the digital topographic data. The building data generation module 153 may extract the information related to the building from the digital topographic data. The information related to the building may include, for example, footprint coordinate information of the building (or outline coordinate information of the building, position information of the building, etc.), height information of the building (e.g., number of floors), usage information of the building, elevation information of the building (e.g., elevation value), and the like. Then, the building data generation module 153 may generate three-dimensional mesh data related to the building based on the outline coordinate information of the building and the height information of the building. In this process, the building data generation module 153 may use a polygonal mesh modeling technique. For example, since each face constituting the building is represented as a polygon (e.g., a triangle), and a set of these polygons may form the entire building shape, the building data generation module 153 may generate the three-dimensional mesh data for the building using the polygonal mesh modeling technique.

Then, the building data generation module 153 may obtain a texture image of the building based on the usage information of the building. Here, the texture image of the building may be an image used to express the appearance of the building. According to an embodiment, the building data generation module 153 may obtain the texture image of the building corresponding to the usage of the building from a building texture database. Here, the building texture database may be stored in an external electronic device (e.g., an external storage device) or the memory 130.

Then, the building data generation module 153 may apply the texture image of the corresponding building to the three-dimensional mesh data related to the building. For example, the building data generation module 153 may apply the texture image to the exterior wall of the building. At this time, the building data generation module 153 may repeatedly apply the texture image according to the number of floors of the building. In this process, the building data generation module 153 may use a UV mapping technique. Here, UV mapping may include a process of assigning 2D image coordinates (U, V) to each vertex of the 3D mesh.

Then, the building data generation module 153 may set the elevation value to the three-dimensional mesh data to which the texture image of the building is applied, based on the elevation value of the building. According to an embodiment, the building data generation module 153 may set the basic elevation value of the building (e.g., the elevation value of the building floor) to the elevation value read from the digital elevation model data. For example, the building data generation module 153 may set the elevation value of the building floor to the elevation value read from the digital elevation model data corresponding to the position of the building. Accordingly, the building data generation module 153 may position the building to fit the terrain. Through the process described above, the building data generation module 153 may generate the three-dimensional mesh data for the building that is matched with the elevation of the terrain and to which the texture image corresponding to the usage of the building is applied. According to an embodiment, the building data generation module 153 may automate the process described above using python code. For example, the building data generation module 153 may automate the process of constructing CGA (Computer-Generated Architecture) information of the building.

The vegetation data generation module 154 may generate three-dimensional sub-data associated with vegetation. According to an embodiment, the vegetation data generation module 154 may generate three-dimensional sub-data associated with the vegetation included in the three-dimensional spatial data, based on the vegetation position information. The vegetation data generation module 154 may add an elevation value of the vegetation to coordinate information of the vegetation included in the vegetation position information. For example, when the coordinate information of the vegetation includes only an x coordinate value and a y coordinate value, the vegetation data generation module 154 may add the elevation value of the vegetation corresponding to a z coordinate value to the coordinate information of the vegetation. According to an embodiment, the vegetation data generation module 154 may set the elevation value of the vegetation to the elevation value read from the digital elevation model data. For example, the vegetation data generation module 154 may set the z coordinate value of the bottom surface of the vegetation to the elevation value read from the digital elevation model data corresponding to the position of the vegetation (the position corresponding to the x coordinate value and the y coordinate value). Accordingly, the vegetation data generation module 154 may position the vegetation to fit the terrain. Then, the vegetation data generation module 154 may generate three-dimensional model data (or three-dimensional mesh data) related to the vegetation based on the coordinate information of the vegetation to which the elevation value is added. For example, the vegetation data generation module 154 may generate the three-dimensional mesh data for the vegetation by arranging a three-dimensional model for the vegetation at the x coordinate value, the y coordinate value, and the z coordinate value of the vegetation. Here, various three-dimensional models for the vegetation may be pre-stored in the memory 130.

The static object data generation module 155 may generate three-dimensional sub-data associated with a static object. According to an embodiment, the static object data generation module 155 may generate three-dimensional sub-data associated with the static object included in the three-dimensional spatial data, based on a tagging table related to the static object. Here, the static object may include a road surface, traffic facilities inside and outside the road (e.g., traffic lights, signs, etc.), buildings, vegetation, and the like. The road surface may include lanes on the road and road surface markings. In addition, the tagging table may be data that maps an identifier of the static object with an image, text, symbol, etc. corresponding to the static object, and may be stored in an external electronic device (e.g., an external storage device) or the memory 130.

The data merging module 156 may generate three-dimensional spatial data by merging a plurality of three-dimensional sub-data. According to an embodiment, the data merging module 156 may generate the three-dimensional spatial data by merging at least two of three-dimensional sub-data associated with the road (e.g., the three-dimensional mesh data for the road), three-dimensional sub-data associated with the terrain (e.g., the three-dimensional mesh data for the terrain), three-dimensional sub-data associated with the building (e.g., the three-dimensional mesh data to which the texture image of the building is applied), three-dimensional sub-data associated with the vegetation (e.g., the three-dimensional mesh data for the vegetation), or three-dimensional sub-data associated with the static object (e.g., the three-dimensional mesh data for the static object). In this process, the data merging module 156 may set position values and elevation values for matching of respective objects represented by different three-dimensional sub-data. For example, the data merging module 156 may set the elevation value of the road in the process of generating the three-dimensional mesh data for the road using the elevation value included in the digital elevation model data generated in the process of generating the three-dimensional mesh data for the terrain. That is, the data merging module 156 may arrange the road to be matched with the elevation of the terrain by setting the elevation of the road to fit the elevation of the terrain on which the road is located. As another example, the data merging module 156 may set the elevation value of the building floor in the process of generating the three-dimensional mesh data for the building using the elevation value included in the digital elevation model data generated in the process of generating the three-dimensional mesh data for the terrain. That is, the data merging module 156 may arrange the building to be matched with the elevation of the terrain by setting the floor elevation of the building to fit the elevation of the terrain on which the building is located. As yet another example, the data merging module 156 may set the elevation value (e.g., z coordinate value) of the bottom surface of the vegetation in the process of generating the three-dimensional mesh data for the vegetation using the elevation value included in the digital elevation model data generated in the process of generating the three-dimensional mesh data for the terrain. That is, the data merging module 156 may arrange the vegetation to be matched with the elevation of the terrain by setting the floor elevation of the vegetation to fit the elevation of the terrain on which the vegetation is located. As yet another example, the data merging module 156 may set the elevation value of the bottom surface of the static object in the process of generating the three-dimensional mesh data for the static object (e.g., traffic facilities such as traffic lights, signs, etc.) using the elevation value included in the digital elevation model data generated in the process of generating the three-dimensional mesh data for the terrain. That is, the data merging module 156 may arrange the static object to be matched with the elevation of the terrain by setting the floor elevation of the static object to fit the elevation of the terrain on which the static object is located.

As described above with respect to the data merging module 156 and the various sub-data generation modules 151, 152, 153, 154, 155, the electronic device 100 according to an embodiment of the present disclosure implements a shared-elevation-reference architecture in which the digital elevation model data generated by the terrain data generation module 152 from the contour line information functions as a common geometric reference frame for all of the plurality of three-dimensional sub-data prior to merging. Specifically, rather than independently generating each of the plurality of three-dimensional sub-data and concatenating the independently-generated three-dimensional sub-data, the electronic device 100 propagates elevation values read from positionally-corresponding entries of the digital elevation model data into the three-dimensional sub-data associated with the road, the three-dimensional sub-data associated with the building, the three-dimensional sub-data associated with the vegetation, and the three-dimensional sub-data associated with the static object, prior to or during merging by the data merging module 156. This shared-elevation-reference architecture is reflected, for example, in: the road data generation module 151 setting the elevation value of the road in the process of generating the three-dimensional mesh data for the road using the elevation value included in the digital elevation model data, as described above with respect to the road data generation module 151; the building data generation module 153 setting the basic elevation value of the building (e.g., the elevation value of the building floor) to the elevation value read from the digital elevation model data corresponding to the position of the building, as described above with respect to the building data generation module 153; the vegetation data generation module 154 setting the z coordinate value of the bottom surface of the vegetation to the elevation value read from the digital elevation model data corresponding to the position of the vegetation, as described above with respect to the vegetation data generation module 154; and the static object data generation module 155 setting the elevation value of the bottom surface of the static object using the elevation value read from the digital elevation model data corresponding to the position of the static object, as described above with respect to the static object data generation module 155.

By virtue of the shared-elevation-reference architecture, the electronic device 100 according to an embodiment of the present disclosure achieves at least the following technical effects that are not achievable by conventional approaches that independently process and concatenate spatial information from heterogeneous sources. First, misalignment artifacts at object boundaries (e.g., the building floating above terrain, the road passing through hillside, or the vegetation embedded below ground level) are eliminated at the time of generation of each three-dimensional sub-data, rather than being corrected by post-merging processing. Second, the computational cost of post-merging geometric correction is reduced because the three-dimensional sub-data merged by the data merging module 156 are already geometrically consistent with respect to elevation. Third, object-category-specific modeling and texturing techniques (e.g., polygonal mesh modeling and UV mapping based on the texture image of the building corresponding to the usage of the building described above with respect to the building data generation module 153, three-dimensional model arrangement based on the coordinate information of the vegetation described above with respect to the vegetation data generation module 154, and tagging-table-based generation of the three-dimensional mesh data for the static object described above with respect to the static object data generation module 155) are preserved without compromising the geometric consistency of the merged three-dimensional spatial data.

The operations performed by the modules 151, 152, 153, 154, 155, 156 of the processor 150 according to an embodiment of the present disclosure are particular to the technical field of three-dimensional spatial data generation and are inherently computational in nature. For example, generation of the three-dimensional mesh data for the road by the road data generation module 151 from the point cloud data using Delaunay triangulation involves processing of point cloud data sets that may include millions of three-dimensional point coordinates and is impractical to perform without computational resources. Similarly, generation of the digital elevation model data by the terrain data generation module 152 from the contour line information using the interpolation method (e.g., the TIN interpolation method or the IDW interpolation method) involves repeated coordinate-based interpolation operations across a raster grid and is similarly impractical to perform manually. Generation of the three-dimensional mesh data for the building by the building data generation module 153 using the polygonal mesh modeling technique and the UV mapping technique to apply the texture image to the exterior wall of the building according to the number of floors of the building involves coordinate transformation operations between three-dimensional vertex coordinates and two-dimensional image coordinates that are inherently performed by computer graphics processing. The propagation of elevation values from the digital elevation model data into the three-dimensional sub-data prior to merging requires positionally-indexed lookups into the digital elevation model data for each non-terrain object, which is similarly inherently computational. Accordingly, the operations described herein are not operations that can be practically performed in the human mind or with pen and paper and are not operations that merely automate a previously manual process; rather, the operations represent specific computational arrangements directed to generating three-dimensional spatial data with cross-category geometric consistency.

According to an embodiment, the processor 150 may generate sub-data associated with the terrain or the static object included in the three-dimensional spatial data based on at least one of an orthophotograph (or a satellite photograph) or land cover data. For example, the processor 150 may generate a texture image of the terrain using at least one of the orthophotograph or the land cover data.

As described above, the electronic device 100 according to an embodiment of the present disclosure may support rapid and precise data construction and updating of three-dimensional spatial data by generating the three-dimensional spatial data utilizing various contents comprising spatial information. Accordingly, the electronic device 100 according to an embodiment of the present disclosure may support more accurate and diverse production and utilization of spatial information in implementing a digital twin based on spatial information.

In addition, the electronic device 100 according to an embodiment of the present disclosure enables generation of three-dimensional spatial data covering city-scale geographic areas from publicly-accessible contents (e.g., the road map data, the digital topographic data, the orthophotograph, and the land cover data obtained from the server operated by the National Geographic Information Institute (NGII), and the vegetation position information obtained from the server operated by the local government) without requiring manual per-object modeling. Because the building data generation module 153 automatically obtains the texture image of the building corresponding to the usage of the building from the building texture database and applies the texture image to the three-dimensional mesh data via the UV mapping technique, the resulting three-dimensional spatial data may exhibit visual fidelity that is suitable for use as photorealistic training data for autonomous driving perception models without requiring manual per-building texture authoring. Furthermore, because the process of constructing the CGA information of the building described above may be automated using python code, and the data conversion, optimization, and extraction operations performed by the terrain data generation module 152 may be automated using GIS software (e.g., QGIS) or a python script, the electronic device 100 supports rapid and precise data construction and updating of three-dimensional spatial data on an ongoing basis as updated source contents become available.

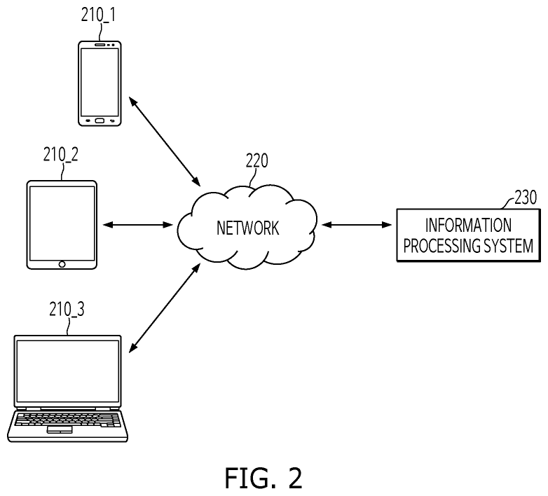

FIG. 2 is a schematic diagram illustrating a configuration in which an information processing system 230 is communicatively connected to a plurality of user terminals 210_1, 210_2, 210_3, in relation to data processing according to an embodiment of the present disclosure. The information processing system 230 may include system(s) capable of providing a data processing service (e.g., a three-dimensional spatial data-based service). In an embodiment, the information processing system 230 may include one or more server devices and/or databases capable of storing, providing, and executing a computer-executable program (e.g., a downloadable application) and data related to the data processing service, or one or more distributed computing devices and/or distributed databases based on a cloud computing service. For example, the information processing system 230 may include separate systems (e.g., servers) for the data processing service.

The data processing service and the like provided by the information processing system 230 may be provided to the user through a data processing application, a web browser application, and the like installed on each of the plurality of user terminals 210_1, 210_2, 210_3.

The plurality of user terminals 210_1, 210_2, 210_3 may communicate with the information processing system 230 through a network 220. The network 220 may be configured to enable communication between the plurality of user terminals 210_1, 210_2, 210_3, and the information processing system 230. The network 220 may be configured as, for example, a wired network such as Ethernet, a wired home network (Power Line Communication), a telephone line communication device, and an RS-serial communication, a wireless network such as a mobile communication network, a wireless LAN (WLAN), Wi-Fi, Bluetooth, and ZigBee, or a combination thereof, depending on the installation environment. The communication method is not limited and may include not only a communication method utilizing a communication network (e.g., a mobile communication network, wired Internet, wireless Internet, broadcasting network, satellite network, etc.) that the network 220 may include, but also short-range wireless communication between the user terminals 210_1, 210_2, 210_3.

For example, the plurality of user terminals 210_1, 210_2, 210_3 may transmit a data processing request, and a command associated with a user request for data processing to the information processing system 230 through the network 220, and the information processing system 230 may receive the data processing request and the command.

In FIG. 2, a mobile phone terminal 210_1, a tablet terminal 210_2, and a PC terminal 210_3 are illustrated as examples of user terminals, but the user terminals 210_1, 210_2, 210_3 are not limited thereto, and may be any computing devices capable of wired and/or wireless communication and capable of installing and executing a data processing application, etc. For example, the user terminal may include a smartphone, a mobile phone, a navigation, a computer, a laptop, a digital broadcasting terminal, a Personal Digital Assistant (PDA), a Portable Multimedia Player (PMP), a tablet PC, a game console, a wearable device, an Internet of Things (IoT) device, a virtual reality (VR) device, an augmented reality (AR) device, and the like. In addition, although three user terminals 210_1, 210_2, 210_3 are illustrated in FIG. 2 as communicating with the information processing system 230 through the network 220, the present disclosure is not limited thereto, and a different number of user terminals may be configured to communicate with the information processing system 230 through the network 220.

When the information processing system 230 provides the three-dimensional spatial data-based service, the information processing system 230 may receive a plurality of contents from the user terminals 210_1, 210_2, 210_3. In this case, the information processing system 230 may generate a plurality of three-dimensional sub-data based on the plurality of contents and generate three-dimensional spatial data by merging the generated plurality of three-dimensional sub-data. For example, the information processing system 230 may generate first three-dimensional sub-data and second three-dimensional sub-data based on each of first content and second content received from the user terminals 210_1, 210_2, 210_3 and generate the three-dimensional spatial data by merging the generated first and second three-dimensional sub-data. Thereafter, the information processing system 230 may transmit the generated three-dimensional spatial data to the user terminals 210_1, 210_2, 210_3.

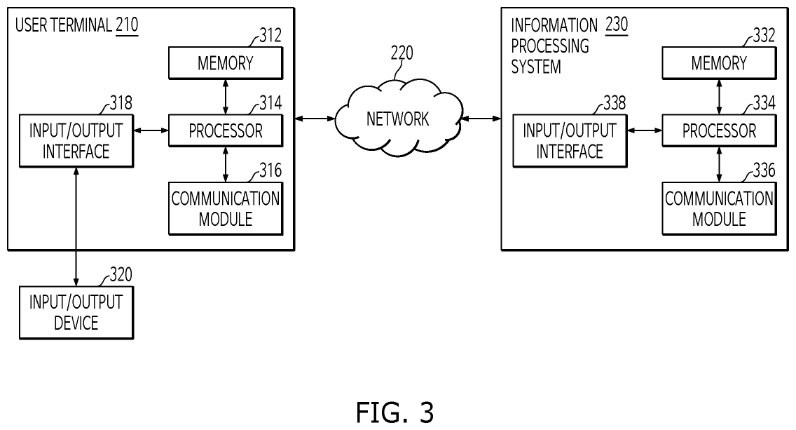

FIG. 3 is a block diagram illustrating an internal configuration of a user terminal 210 and the information processing system 230 according to an embodiment of the present disclosure. The user terminal 210 may refer to any computing device capable of executing a data processing application, etc. and capable of wired/wireless communication, and may include, for example, the mobile phone terminal 210_1, the tablet terminal 210_2, the PC terminal 210_3, etc. of FIG. 2. As illustrated, the user terminal 210 may include a memory 312, a processor 314, a communication module 316, and an input/output interface 318. Similarly, the information processing system 230 may include a memory 332, a processor 334, a communication module 336, and an input/output interface 338. As illustrated in FIG. 3, the user terminal 210 and the information processing system 230 may be configured to communicate information and/or data through the network 220 using respective communication modules 316, 336. In addition, an input/output device 320 may be configured to input information and/or data to the user terminal 210 through the input/output interface 318 or to output information and/or data generated from the user terminal 210.

The memories 312, 332 may include any non-transitory computer-readable recording medium. According to an embodiment, the memories 312, 332 may include a permanent mass storage device such as a read only memory (ROM), a disk drive, a solid state drive (SSD), a flash memory, and the like. As another example, a non-volatile mass storage device such as ROM, SSD, flash memory, disk drive, etc. may be included in the user terminal 210 or the information processing system 230 as a separate permanent storage device distinct from the memory. In addition, an operating system and at least one program code (e.g., code for an application related to the data processing service, etc.) may be stored in the memories 312, 332.

These software components may be loaded from a computer-readable recording medium separate from the memories 312, 332. Such a separate computer-readable recording medium may include a recording medium directly connectable to the user terminal 210 and the information processing system 230, for example, may include a computer-readable recording medium such as a floppy drive, a disk, a tape, a DVD/CD-ROM drive, a memory card, and the like. As another example, the software components may be loaded into the memories 312, 332 through the communication modules 316, 336 rather than the computer-readable recording medium. For example, at least one program may be loaded into the memories 312, 332 based on a computer program (e.g., an application related to the data processing service, etc.) installed by files provided through the network 220 by developers or a file distribution system that distributes installation files of applications.

The processors 314, 334 may be configured to process instructions of a computer program by performing basic arithmetic, logic, and input/output operations. The instructions may be provided to the processors 314, 334 by the memories 312, 332 or the communication modules 316, 336. For example, the processors 314, 334 may be configured to execute received instructions according to program code stored in a recording device such as the memories 312, 332.

The communication modules 316, 336 may provide a configuration or function for the user terminal 210 and the information processing system 230 to communicate with each other through the network 220 and may provide a configuration or function for the user terminal 210 and/or the information processing system 230 to communicate with another user terminal or another system (e.g., a separate cloud system, etc.). For example, a request or data (e.g., a data processing request or data, etc.) generated by the processor 314 of the user terminal 210 according to program code stored in a recording device such as the memory 312 may be transmitted to the information processing system 230 through the network 220 under the control of the communication module 316. Conversely, a control signal or command provided under the control of the processor 334 of the information processing system 230 may be received by the user terminal 210 through the communication module 336 and the network 220 and the communication module 316 of the user terminal 210.

The input/output interface 318 may be a means for interfacing with the input/output device 320. As an example, the input device may include a device such as a camera comprising an audio sensor and/or an image sensor, a keyboard, a microphone, a mouse, and the like, and the output device may include a device such as a display, a speaker, a haptic feedback device, and the like. As another example, the input/output interface 318 may be a means for interfacing with a device such as a touch screen in which a configuration or function for performing input and output is integrated into one. In FIG. 3, the input/output device 320 is illustrated as not being included in the user terminal 210, but the present disclosure is not limited thereto, and the input/output device 320 may be configured as one device with the user terminal 210. In addition, the input/output interface 338 of the information processing system 230 may be a means for interfacing with a device (not illustrated) for input or output that is connected to the information processing system 230 or that the information processing system 230 may include. Although the input/output interfaces 318, 338 are illustrated as elements separately configured from the processors 314, 334 in FIG. 3, the present disclosure is not limited thereto, and the input/output interfaces 318, 338 may be configured to be included in the processors 314, 334.

The user terminal 210 and the information processing system 230 may include more components than the components of FIG. 3. However, there is no need to clearly illustrate most of the conventional technical components. In an embodiment, the user terminal 210 may be implemented to include at least some of the input/output devices 320 described above. In addition, the user terminal 210 may further include other components such as a transceiver, a Global Positioning System (GPS) module, a camera, various sensors, a database, and the like. For example, when the user terminal 210 is a smartphone, the user terminal 210 may include components generally included in a smartphone, and for example, various components such as an acceleration sensor, a gyro sensor, a microphone module, a camera module, various physical buttons, buttons using a touch panel, input/output ports, a vibrator for vibration, and the like, may be implemented to be further included in the user terminal 210.

According to an embodiment, the processor 314 of the user terminal 210 may be configured to operate a data processing application or a web browser application that provides a data processing service. At this time, program code associated with the corresponding application may be loaded into the memory 312 of the user terminal 210. While the application is running, the processor 314 of the user terminal 210 may receive information and/or data provided from the input/output device 320 through the input/output interface 318 or receive information and/or data from the information processing system 230 through the communication module 316, and process the received information and/or data and store the received information and/or data in the memory 312. In addition, the information and/or data may be provided to the information processing system 230 through the communication module 316.

While the data processing application is running, the processor 314 may receive voice data, text, images, videos, and the like that are input or selected through an input device such as a touch screen connected to the input/output interface 318, a keyboard, a camera comprising an audio sensor and/or an image sensor, a microphone, and the like, and may store the received voice data, text, images, and/or videos, and the like in the memory 312 or provide the received voice data, text, images, and/or videos, and the like to the information processing system 230 through the communication module 316 and the network 220. In an embodiment, the processor 314 may receive a user input that is input through the input device and provide data/request corresponding to the received user input to the information processing system 230 through the network 220 and the communication module 316.

The processor 314 of the user terminal 210 may transmit information and/or data to the input/output device 320 through the input/output interface 318 to output the information and/or data. For example, the processor 314 of the user terminal 210 may output processed information and/or data through the output device 320 such as a display output capable device (e.g., a touch screen, a display, etc.), a voice output capable device (e.g., a speaker), and the like.

The processor 334 of the information processing system 230 may be configured to manage, process, and/or store information and/or data received from the plurality of user terminals 210 and/or a plurality of external systems. The information and/or data processed by the processor 334 may be provided to the user terminal 210 through the communication module 336 and the network 220.

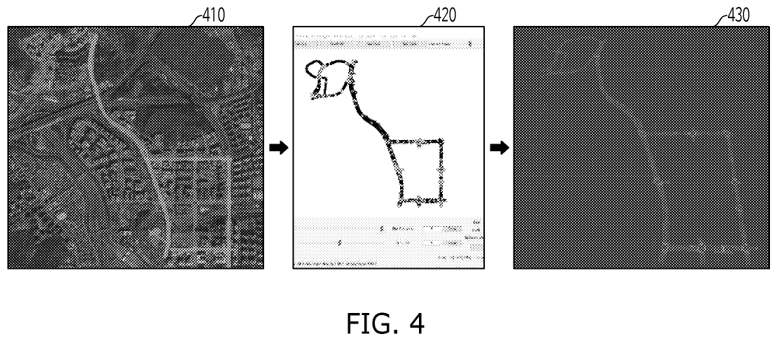

FIG. 4 illustrates a method of generating three-dimensional sub-data associated with a road according to an embodiment of the present disclosure. Referring to FIG. 4, the processor (e.g., the processor 150 of FIG. 1) of the electronic device for generating three-dimensional spatial data (e.g., the electronic device 100 of FIG. 1) may generate three-dimensional sub-data associated with the road, based on contents (e.g., road map data 410) received from an external electronic device through the communication circuit (e.g., the communication circuit 110 of FIG. 1). For example, the processor may generate the three-dimensional sub-data associated with the road included in the three-dimensional spatial data, based on the road map data 410 received from the external electronic device connected through the communication circuit.

According to an embodiment, the processor may generate three-dimensional mesh data 430 for the road based on point cloud data included in the road map data 410 using Delaunay triangulation, etc. Here, the three-dimensional mesh data 430 for the road may have a data form (or format) that is easy to output for autonomous driving simulation or three-dimensional asset (3D asset). In a process of generating the three-dimensional mesh data 430 for the road based on the point cloud data included in the road map data 410, the processor may convert the format of the data. For example, the processor may convert the point cloud data included in the road map data 410 into data 420 having an LAS file format, which is a file format for the exchange of three-dimensional point cloud data.

According to an embodiment, the processor may set an elevation value of the road in the process of generating the three-dimensional mesh data 430 for the road using an elevation value included in the digital elevation model data generated in the process of generating the three-dimensional mesh data for the terrain. That is, the processor may support the road to be arranged matching the elevation of the terrain by setting the elevation of the road to fit the elevation of the terrain on which the road is located.

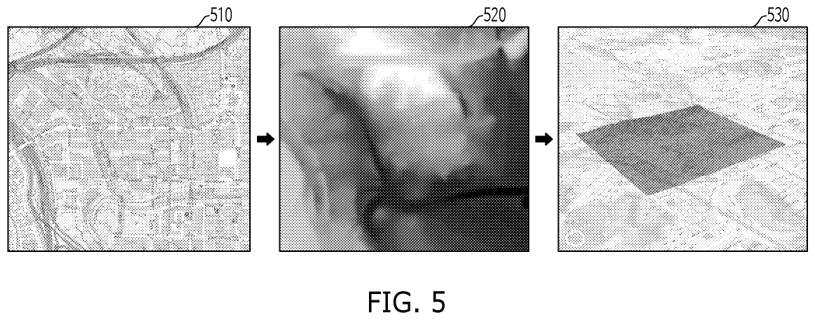

FIG. 5 illustrates a method of generating three-dimensional sub-data associated with terrain according to an embodiment of the present disclosure. Referring to FIG. 5, the processor (e.g., the processor 150 of FIG. 1) of the electronic device for generating three-dimensional spatial data (e.g., the electronic device 100 of FIG. 1) may generate three-dimensional sub-data associated with the terrain, based on contents (e.g., digital topographic data 510) received from an external electronic device through the communication circuit (e.g., the communication circuit 110 of FIG. 1). For example, the processor may generate the three-dimensional sub-data associated with the terrain included in the three-dimensional spatial data, based on the digital topographic data 510 received from the external electronic device connected through the communication circuit.

According to an embodiment, the processor may generate digital elevation model data 520 based on contour line information included in the digital topographic data 510 and generate three-dimensional mesh data 530 for the terrain based on the digital elevation model data 520. The processor may extract the contour line information included in the digital topographic data 510. At this time, when the elevation value of the contour line includes characters, the processor may convert the elevation value into numbers. Then, the processor may generate the digital elevation model data 520 using an interpolation method (e.g., a TIN interpolation method or an IDW interpolation method). At this time, the digital elevation model data 520 may be generated in a raster format. Then, the processor may generate the three-dimensional mesh data 530 for the terrain according to the elevation value included in the digital elevation model data 520 using triangulation (e.g., Delaunay triangulation). For example, the processor may generate a TIN terrain model according to the DEM elevation height.

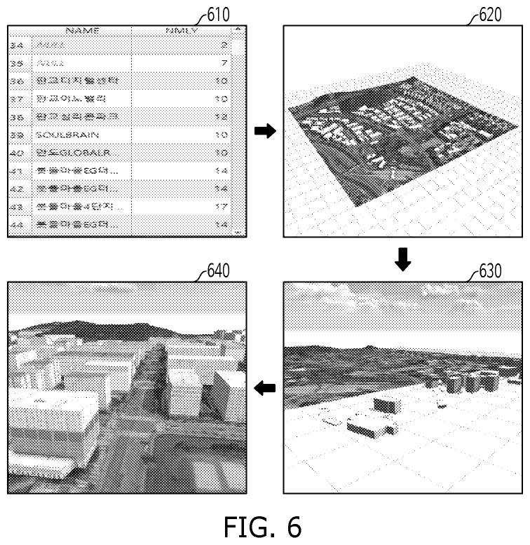

FIG. 6 illustrates a method of generating three-dimensional sub-data associated with a building according to an embodiment of the present disclosure. Referring to FIG. 6, the processor (e.g., the processor 150 of FIG. 1) of the electronic device for generating three-dimensional spatial data (e.g., the electronic device 100 of FIG. 1) may generate three-dimensional sub-data associated with the building, based on contents (e.g., digital topographic data) received from an external electronic device through the communication circuit (e.g., the communication circuit 110 of FIG. 1). For example, the processor may generate the three-dimensional sub-data associated with the building included in the three-dimensional spatial data, based on the digital topographic data received from the external electronic device connected through the communication circuit.

According to an embodiment, the processor may extract information related to the building 610 from the digital topographic data. The information related to the building 610 may include, for example, outline coordinate information of the building (or position information of the building), height information of the building (e.g., number of floors), usage information of the building, elevation information of the building (e.g., elevation value), and the like. Then, the processor may generate three-dimensional mesh data 620 related to the building based on the outline coordinate information of the building and the height information of the building included in the information related to the building 610. In this process, the processor may use a polygonal mesh modeling technique. Then, the processor may obtain a texture image of the building based on the usage information of the building. Here, the texture image of the building may be an image used to express the appearance of the building. According to an embodiment, the processor may obtain the texture image of the building corresponding to the usage of the building from a building texture database stored in an external electronic device (e.g., an external storage device) or the memory (e.g., the memory 130 of FIG. 1). Then, the processor may apply the texture image of the corresponding building to the three-dimensional mesh data 620 related to the building to obtain three-dimensional mesh data 630 in which the appearance of the building is expressed. At this time, the processor may repeatedly apply the texture image according to the number of floors of the building. In this process, the processor may use a UV mapping technique. Then, the processor may set the basic elevation value of the building (e.g., the elevation value of the building floor) to the elevation value read from the digital elevation model data. For example, the processor may set the elevation value of the building floor to the elevation value read from the digital elevation model data corresponding to the position of the building. Accordingly, the processor may position the building to fit the terrain. Through the process described above, the processor may generate three-dimensional mesh data 640 for the building that is matched with the elevation of the terrain and to which the texture image corresponding to the usage of the building is applied. According to an embodiment, the process of constructing the CGA information of the building (e.g., the three-dimensional mesh data 640 for the building) described above may be automated using python code or the like.

According to an embodiment, the processor may set the elevation value of the building in the process of generating the three-dimensional mesh data 640 for the building using the elevation value included in the digital elevation model data generated in the process of generating the three-dimensional mesh data for the terrain. That is, the processor may support the building to be arranged matching the elevation of the terrain by setting the elevation of the building to fit the elevation of the terrain on which the building is located.

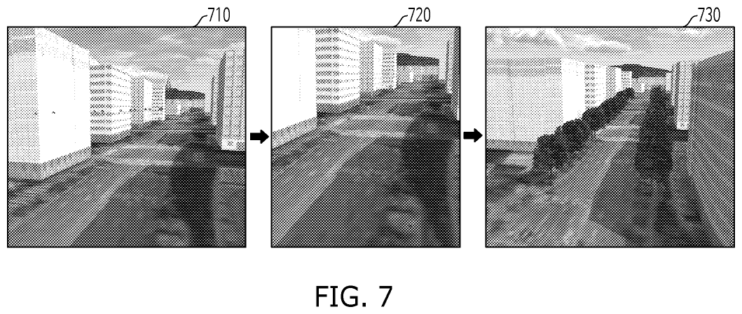

FIG. 7 illustrates a method of generating three-dimensional sub-data associated with vegetation according to an embodiment of the present disclosure. Referring to FIG. 7, the processor (e.g., the processor 150 of FIG. 1) of the electronic device for generating three-dimensional spatial data (e.g., the electronic device 100 of FIG. 1) may generate three-dimensional sub-data associated with the vegetation, based on contents (e.g., data 710 comprising vegetation position information) received from an external electronic device through the communication circuit (e.g., the communication circuit 110 of FIG. 1). For example, the processor may generate the three-dimensional sub-data associated with the vegetation included in the three-dimensional spatial data, based on the vegetation position information received from the external electronic device connected through the communication circuit.

According to an embodiment, the processor may add the elevation value of the vegetation to the coordinate information of the vegetation included in the vegetation position information. For example, when the coordinate information of the vegetation includes only an x coordinate value and a y coordinate value, the processor may obtain data 720 in which the elevation value of the vegetation corresponding to a z coordinate value is added to the coordinate information of the vegetation. According to an embodiment, the processor may set the elevation value of the vegetation to the elevation value read from the digital elevation model data. For example, the processor may set the z coordinate value of the bottom surface of the vegetation to the elevation value read from the digital elevation model data corresponding to the position of the vegetation (the position corresponding to the x coordinate value and the y coordinate value). Accordingly, the processor may position the vegetation to fit the terrain.

Then, the processor may generate three-dimensional mesh data (or three-dimensional model data) 730 related to the vegetation based on the coordinate information of the vegetation to which the elevation value is added. For example, the processor may generate the three-dimensional mesh data 730 for the vegetation by arranging a three-dimensional model for the vegetation at the x coordinate value, the y coordinate value, and the z coordinate value of the vegetation. According to an embodiment, the three-dimensional model for the vegetation may be pre-stored in the memory (e.g., the memory 130 of FIG. 1).

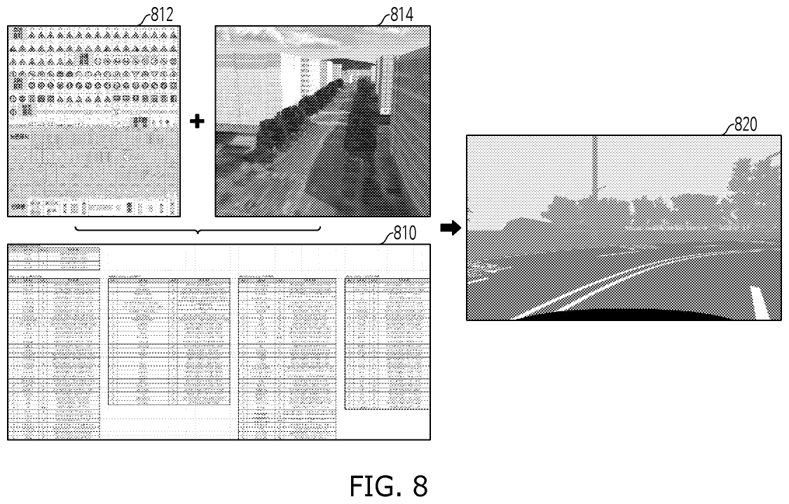

FIG. 8 illustrates a method of generating three-dimensional sub-data associated with a static object according to an embodiment of the present disclosure. Referring to FIG. 8, the processor (e.g., the processor 150 of FIG. 1) of the electronic device for generating three-dimensional spatial data (e.g., the electronic device 100 of FIG. 1) may generate three-dimensional sub-data associated with the static object, based on contents (e.g., a tagging table 810 related to the static object) received from an external electronic device through the communication circuit (e.g., the communication circuit 110 of FIG. 1). For example, the processor may generate the three-dimensional sub-data associated with the static object included in the three-dimensional spatial data, based on the tagging table 810 related to the static object received from the external electronic device connected through the communication circuit. In some embodiments, the tagging table 810 related to the static object may be pre-stored in the memory (e.g., the memory 130 of FIG. 1) of the electronic device. In this case, the processor may use the tagging table 810 related to the static object stored in the memory. The tagging table 810 related to the static object may include data in which an identifier of the static object is mapped with an image, text, symbol, etc. corresponding to the static object. Here, the static object may include a road surface comprising lanes on the road and road surface markings, traffic facilities inside and outside the road comprising traffic lights and signs, buildings, vegetation, and the like. For example, three-dimensional mesh data for the static object may be generated based on the tagging table 810 in which images 812 of the road surface and the traffic facilities inside and outside the road and images 814 of buildings and vegetation are mapped with respective identifiers.

According to an embodiment, the processor may set the elevation value of the static object in the process of generating the three-dimensional mesh data for the static object using the elevation value included in the digital elevation model data generated in the process of generating the three-dimensional mesh data for the terrain. That is, the processor may support the static object to be arranged matching the elevation of the terrain by setting the elevation of the static object to fit the elevation of the terrain on which the static object is located.

According to an embodiment, the type of each object included in the three-dimensional spatial data (e.g., vegetation, road surface, building, traffic light, sign, etc.) may be tagged and stored together. Accordingly, using the three-dimensional spatial data, not only a simulation RGB image viewed from the driver's seat of the vehicle, but also a semantic segmentation image 820 corresponding to the simulation RGB image viewed from the vehicle may be generated.

As described above with respect to FIG. 8, the three-dimensional spatial data generated according to an embodiment of the present disclosure may be utilized to generate not only the simulation RGB image viewed from the driver's seat of the vehicle but also the semantic segmentation image 820 corresponding to the simulation RGB image viewed from the vehicle. Such utilization represents a specific practical application of the three-dimensional spatial data generated by the electronic device 100. For example, the simulation RGB image and the corresponding semantic segmentation image 820 may be provided as training data or validation data to a perception model of an autonomous driving system, thereby reducing the cost and time required to acquire real-world driving data with manually annotated semantic segmentation labels. As another example, the three-dimensional spatial data generated according to an embodiment of the present disclosure may be provided to a digital twin platform that monitors physical infrastructure, an augmented reality (AR) rendering pipeline, or a virtual reality (VR) rendering pipeline. Because the three-dimensional spatial data is geometrically consistent across object categories by virtue of the shared-elevation-reference architecture, such downstream simulation, training, and rendering systems may operate on the three-dimensional spatial data without requiring additional geometric correction stages, thereby reducing latency and computational overhead in such downstream systems.

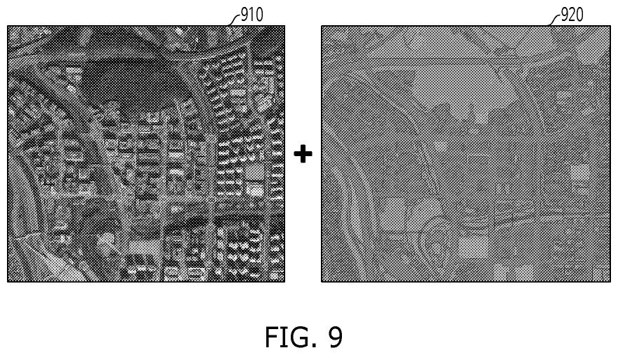

FIG. 9 illustrates a method of generating three-dimensional sub-data associated with terrain or a static object according to an embodiment of the present disclosure. Referring to FIG. 9, the processor (e.g., the processor 150 of FIG. 1) of the electronic device for generating three-dimensional spatial data (e.g., the electronic device 100 of FIG. 1) may generate three-dimensional sub-data associated with the terrain or the static object, based on contents (e.g., an orthophotograph 910 and/or land cover data 920) received from an external electronic device through the communication circuit (e.g., the communication circuit 110 of FIG. 1). For example, the processor may generate the three-dimensional sub-data associated with the terrain or the static object included in the three-dimensional spatial data, based on at least one of the orthophotograph 910 or the land cover data 920 received from the external electronic device connected through the communication circuit. According to an embodiment, the processor may generate a texture image of the terrain using at least one of the orthophotograph 910 or the land cover data 920.

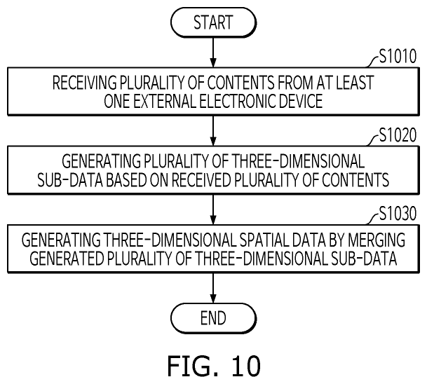

FIG. 10 illustrates a method of generating three-dimensional spatial data according to an embodiment of the present disclosure. Referring to FIG. 10, the processor (e.g., the processor 150 of FIG. 1) of the electronic device for generating three-dimensional spatial data (e.g., the electronic device 100 of FIG. 1) may receive a plurality of contents from at least one external electronic device, in step 1010 (S1010). For example, the processor may receive the plurality of contents from at least one external electronic device connected through the communication circuit (e.g., the communication circuit 110 of FIG. 1). Here, the contents include source information (or data) for generating three-dimensional spatial data and may be provided in various forms (or formats). For example, the contents may include at least one of road map data, digital topographic data, vegetation position information, a tagging table related to a static object comprising a road surface, an orthophotograph, or land cover data.

In step 1020 (S1020), the processor may generate a plurality of three-dimensional sub-data based on the received plurality of contents. According to an embodiment, the processor may generate three-dimensional sub-data associated with the road included in the three-dimensional spatial data, based on point cloud data included in the road map data. For example, the processor may generate three-dimensional mesh data for the road based on the point cloud data included in the road map data using Delaunay triangulation, etc. In addition, the processor may set the elevation value of the road using the elevation value included in the digital elevation model data.

According to an embodiment, the processor may generate three-dimensional sub-data associated with the terrain included in the three-dimensional spatial data, based on contour line information included in the digital topographic data. For example, the processor may extract the contour line information included in the digital topographic data, and when the elevation value of the contour line includes characters, convert the elevation value of the contour line into numbers, then generate digital elevation model data using an interpolation method (e.g., a TIN interpolation method or an IDW interpolation method), and generate three-dimensional mesh data for the terrain according to the elevation value included in the digital elevation model data using triangulation (e.g., Delaunay triangulation).

According to an embodiment, the processor may generate three-dimensional sub-data associated with the building included in the three-dimensional spatial data, based on information related to the building included in the digital topographic data. For example, the processor may extract the information related to the building from the digital topographic data, generate three-dimensional mesh data related to the building based on the outline coordinate information of the building and the height information of the building among the extracted information related to the building, obtain a texture image of the building based on the usage information of the building among the extracted information related to the building, and apply the texture image of the corresponding building to the three-dimensional mesh data related to the building. In addition, the processor may set the basic elevation value of the building (e.g., the elevation value of the building floor) to the elevation value read from the digital elevation model data.

According to an embodiment, the processor may generate three-dimensional sub-data associated with the vegetation included in the three-dimensional spatial data, based on the vegetation position information. For example, the processor may add the elevation value of the vegetation to the coordinate information of the vegetation included in the vegetation position information. When the coordinate information of the vegetation includes only an x coordinate value and a y coordinate value, the processor may add the elevation value of the vegetation corresponding to a z coordinate value to the coordinate information of the vegetation. In addition, the processor may set the elevation value of the vegetation to the elevation value read from the digital elevation model data. For example, the processor may set the z coordinate value of the bottom surface of the vegetation to the elevation value read from the digital elevation model data corresponding to the position of the vegetation (the position corresponding to the x coordinate value and the y coordinate value).

According to an embodiment, the processor may generate three-dimensional sub-data associated with the static object included in the three-dimensional spatial data, based on a tagging table related to the static object (e.g., traffic facilities such as traffic lights, signs, etc.). For example, the processor may generate three-dimensional mesh data for the static object using an image, text, symbol, etc. corresponding to the static object corresponding to an identifier of the static object in the tagging table. In addition, the processor may set the elevation value of the bottom surface of the static object using the elevation value included in the digital elevation model data.

In step 1030 (S1030), the processor may generate three-dimensional spatial data by merging the generated plurality of three-dimensional sub-data. For example, the processor may generate the three-dimensional spatial data by merging at least two of three-dimensional sub-data associated with the road, three-dimensional sub-data associated with the terrain, three-dimensional sub-data associated with the building, three-dimensional sub-data associated with the vegetation, or three-dimensional sub-data associated with the static object.

The flowchart and the description described above are merely examples and may be implemented differently in some embodiments. For example, in some embodiments, the order of each step may be changed, some steps may be repeatedly performed, some steps may be omitted, or some steps may be added.

The method described above may be provided as a computer program stored in a computer-readable recording medium for execution on a computer. The medium may be one that continuously stores the computer-executable program or temporarily stores the computer-executable program for execution or download. In addition, the medium may be various recording means or storage means in the form of a single or several pieces of hardware combined and is not limited to a medium directly connected to a certain computer system but may be one that exists in a distributed manner on a network. Examples of the medium may include those configured to store program instructions, including magnetic media such as hard disks, floppy disks, and magnetic tapes, optical recording media such as CD-ROMs and DVDs, magneto-optical media such as floptical disks, and ROMs, RAMs, flash memories, and the like. In addition, examples of other media may include recording media or storage media managed by app stores that distribute applications, sites that supply or distribute various other software, servers, and the like.

The methods, operations, or techniques of the present disclosure may be implemented by various means. For example, such techniques may be implemented in hardware, firmware, software, or a combination thereof. Those skilled in the art will understand that the various exemplary logical blocks, modules, circuits, and algorithm steps described in connection with the disclosure herein may be implemented in electronic hardware, computer software, or combinations of both. To clearly illustrate this interchangeability of hardware and software, various exemplary components, blocks, modules, circuits, and steps have been described above generally in terms of their functionality. Whether such functionality is implemented as hardware or software depends on the particular application and design requirements imposed on the overall system. Those skilled in the art may implement the described functionality in various ways for each particular application, but such implementations should not be interpreted as causing a departure from the scope of the present disclosure.

In a hardware implementation, the processing units used to perform the techniques may be implemented within one or more ASICs, DSPs, digital signal processing devices (DSPDs), programmable logic devices (PLDs), field programmable gate arrays (FPGAs), processors, controllers, microcontrollers, microprocessors, electronic devices, other electronic units designed to perform the functions described in the present disclosure, a computer, or a combination thereof.

Accordingly, the various exemplary logical blocks, modules, and circuits described in connection with the present disclosure may be implemented or performed with a general-purpose processor, a DSP, an ASIC, an FPGA or other programmable logic device, discrete gate or transistor logic, discrete hardware components, or any combination of those designed to perform the functions described herein. A general-purpose processor may be a microprocessor, but in the alternative, the processor may be any conventional processor, controller, microcontroller, or state machine. The processor may also be implemented as a combination of computing devices, for example, a combination of a DSP and a microprocessor, a plurality of microprocessors, one or more microprocessors in conjunction with a DSP core, or any other configuration of combinations.

In firmware and/or software implementations, the techniques may be implemented as instructions stored on a computer-readable medium such as random access memory (RAM), read-only memory (ROM), non-volatile random access memory (NVRAM), programmable read-only memory (PROM), erasable programmable read-only memory (EPROM), electrically erasable PROM (EEPROM), flash memory, compact disc (CD), magnetic or optical data storage device, and the like. The instructions may be executable by one or more processors and may cause the processor(s) to perform certain aspects of the functionality described in the present disclosure.

When implemented in software, the techniques described above may be stored on or transmitted over as one or more instructions or code on a computer-readable medium. Computer-readable media include both computer storage media and communication media including any medium that facilitates transfer of a computer program from one place to another. Storage media may be any available media that can be accessed by a computer. By way of non-limiting example, such computer-readable media may include RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium.

For example, if the software is transmitted from a website, server, or other remote source using coaxial cable, fiber optic cable, twisted pair, digital subscriber line (DSL), or wireless technologies such as infrared, radio, and microwave, then the coaxial cable, fiber optic cable, twisted pair, digital subscriber line, or wireless technologies such as infrared, radio, and microwave are included within the definition of medium. Disk and disc, as used herein, includes CD, laser disc, optical disc, digital versatile disc (DVD), floppy disk, and Blu-ray disc, where disks usually reproduce data magnetically, while discs reproduce data optically with lasers. Combinations of the above should also be included within the scope of computer-readable media.

A software module may reside in RAM memory, flash memory, ROM memory, EPROM memory, EEPROM memory, registers, hard disk, a removable disk, a CD-ROM, or any other form of storage medium known. An exemplary storage medium may be coupled to the processor such that the processor can read information from, or write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

Although the embodiments described above have been described as utilizing aspects of the presently disclosed subject matter on one or more standalone computer systems, the present disclosure is not limited thereto and may be implemented in connection with any computing environment, such as a network or distributed computing environment. Furthermore, aspects of the subject matter in the present disclosure may be implemented in a plurality of processing chips or devices, and storage may also be similarly affected across the plurality of devices. Such devices may include PCs, network servers, and portable devices.

Although the present disclosure has been described in connection with some embodiments in the present specification, various modifications and changes may be made without departing from the scope of the present disclosure that may be understood by those of ordinary skill in the art to which the invention of the present disclosure pertains. In addition, such modifications and changes should be considered to fall within the scope of the claims appended to the present specification.

What is claimed is:

1. An apparatus for a vehicle, the apparatus comprising:
a communication circuit;
a memory; and
a processor operatively connected to the communication circuit and the memory, wherein the memory stores instructions configured to be executed by the processor to cause the apparatus to:
receive, via the communication circuit, a plurality of contents from at least one external electronic device,
generate, based on the plurality of contents, a plurality of three-dimensional (3D) sub-data,
generate 3D spatial data by merging the plurality of 3D sub-data,
output, based on the 3D spatial data, a 3D simulation map for autonomous driving simulation of the vehicle, and
control, using the 3D simulation map, a simulated operation of the vehicle.

2. The apparatus of claim 1, wherein the plurality of contents comprise road map data, and wherein the instructions are configured to be executed by the processor to cause the apparatus to generate, based on point cloud data included in the road map data, first 3D sub-data associated with road information included in the 3D spatial data.

3. The apparatus of claim 1, wherein the plurality of contents comprise digital topographic data, and wherein the instructions are configured to be executed by the processor to cause the apparatus to generate, based on contour line information included in the digital topographic data, second 3D sub-data associated with terrain information included in the 3D spatial data.

4. The apparatus of claim 3, wherein the instructions are configured to be executed by the processor to cause the apparatus to:
generate, based on the contour line information and using interpolation, digital elevation model (DEM) data, and
generate, based on the DEM data and using triangulation, the second 3D sub-data associated with the terrain information.

5. The apparatus of claim 1, wherein the plurality of contents comprise digital topographic data, and wherein the instructions are configured to be executed by the processor to cause the apparatus to generate, based on building information included in the digital topographic data, third 3D sub-data associated with building information included in the 3D spatial data.

6. The apparatus of claim 5, wherein the instructions are configured to be executed by the processor to cause the apparatus to:
based on outline coordinate information of a specific building and height information of the specific building among the building information, generate 3D mesh data related to the specific building,
obtain, based on usage information of the specific building among the building information, a texture image of the specific building,
update, based on the texture image of the specific building, the 3D mesh data, and
based on elevation information of the specific building among the building information, set an elevation value to the updated 3D mesh data.

7. The apparatus of claim 1, wherein the plurality of contents comprise vegetation position information, wherein the vegetation position information comprises coordinate information of a specific vegetation object, and wherein the instructions are configured to be executed by the processor to cause the apparatus to:
generate, based on the vegetation position information, fourth 3D sub-data associated with vegetation information included in the 3D spatial data by:
updating the coordinate information of the specific vegetation object by adding an elevation value of the specific vegetation object to the coordinate information, and
generating, based on the updated coordinate information, 3D model data related to the specific vegetation object.

8. The apparatus of claim 1, wherein the instructions are configured to be executed by the processor to cause the apparatus to generate, based on a tagging table, fifth 3D sub-data associated with static object information included in the 3D spatial data, and wherein the static object information comprises road surface information, and the tagging table is related to the static object information.

9. The apparatus of claim 1, wherein the plurality of contents comprise at least one of an orthophotograph or land cover data, and wherein the instructions are configured to be executed by the processor to cause the apparatus to generate, based on the at least one of the orthophotograph or the land cover data, sixth 3D sub-data associated with terrain information or static object information included in the 3D spatial data, wherein the sixth 3D sub-data associated with the terrain information is generated by generating a texture image associated with the terrain information.

10. A method performed by an apparatus, the method comprising:
receiving, via a communication circuit, a plurality of contents from at least one external electronic device;
generating, based on the plurality of contents, a plurality of three-dimensional (3D) sub-data;
generating 3D spatial data by merging the plurality of 3D sub-data;
outputting, based on the 3D spatial data, a 3D simulation map for autonomous driving simulation of a vehicle; and
controlling, using the 3D simulation map, a simulated operation of the vehicle.

11. The method of claim 10, wherein the plurality of contents comprise road map data, and wherein the generating of the plurality of 3D sub-data comprises:
generating, based on point cloud data included in the road map data, first 3D sub-data associated with road information included in the 3D spatial data.

12. The method of claim 10, wherein the plurality of contents comprise digital topographic data, and wherein the generating of the plurality of 3D sub-data comprises:
generating, based on contour line information included in the digital topographic data, second 3D sub-data associated with terrain information included in the 3D spatial data.

13. The method of claim 12, wherein the generating of the plurality of 3D sub-data further comprises:
generating, based on the contour line information and using interpolation, digital elevation model (DEM) data; and
generating, based on the DEM data and using triangulation, the second 3D sub-data associated with the terrain information.

14. The method of claim 10, wherein the plurality of contents comprise digital topographic data, and wherein the generating of the plurality of 3D sub-data comprises:
generating, based on building information included in the digital topographic data, third 3D sub-data associated with building information included in the 3D spatial data.

15. The method of claim 14, wherein the generating of the plurality of 3D sub-data further comprises:
based on outline coordinate information of a specific building and height information of the specific building among the building information, generating 3D mesh data related to the specific building,
obtaining, based on usage information of the specific building among the building information, a texture image of the specific building,
updating, based on the texture image of the specific building, the 3D mesh data, and
based on elevation information of the specific building among the building information, setting an elevation value to the updated 3D mesh data.

16. The method of claim 10, wherein the plurality of contents comprise vegetation position information, wherein the vegetation position information comprises coordinate information of a specific vegetation object, and wherein the generating of the plurality of 3D sub-data comprises:
generating, based on the vegetation position information, fourth 3D sub-data associated with vegetation information included in the 3D spatial data by:
updating the coordinate information of the specific vegetation object by adding an elevation value of the specific vegetation object to the coordinate information, and
generating, based on the updated coordinate information, 3D model data related to the specific vegetation object.

17. The method of claim 10, wherein the generating of the plurality of 3D sub-data comprises:
generating, based on a tagging table, fifth three-dimensional sub-data associated with static object information included in the 3D spatial data, wherein the static object information comprises road surface information, and wherein the tagging table is related to the static object information.

18. The method of claim 10, wherein the plurality of contents comprise at least one of an orthophotograph or land cover data, and wherein the generating of the plurality of 3D sub-data comprises:
generating, based on the at least one of the orthophotograph or the land cover data, sixth 3D sub-data associated with terrain information or static object information included in the 3D spatial data, wherein the sixth 3D sub-data associated with the terrain information is generated by generating a texture image associated with the terrain information.

19. An apparatus for a vehicle, the apparatus comprising:
a communication circuit;
a processor; and
a memory storing instructions configured to be executed by the processor to cause the apparatus to:
receive, via the communication circuit, digital topographic data comprising contour line information and road map data comprising point cloud data,
generate digital elevation model (DEM) data in a raster format by interpolating the contour line information,
generate first three-dimensional (3D) sub-data associated with terrain by performing triangulation on the DEM data,
generate second 3D sub-data associated with a road by:
converting the point cloud data into a 3D mesh for the road;
performing a positionally-indexed lookup in the DEM data to retrieve an elevation value corresponding to a location of the road; and
setting a base elevation for the 3D mesh to the retrieved elevation value corresponding to the location of the road,
generate 3D spatial data by merging the first 3D sub-data and the second 3D sub-data,
generate a semantic segmentation image corresponding to a simulation image viewed from the vehicle,
input the semantic segmentation image to an autonomous driving perception model, and
control, based on an output of the autonomous driving perception model, a simulated operation of the vehicle.

20. The apparatus of claim 19, wherein the base elevation is set for the 3D mesh based on an elevation value of the DEM data corresponding to the location of the road such that the 3D mesh for the road is geometrically consistent with the first 3D sub-data associated with terrain.
